(19) United States
(12) Patent Application Publication
(10) Pub. No.: US 2025/0386670 A1
(43) Pub. Date: Dec. 18, 2025

(54) DISPLAY DEVICE AND DISPLAY SYSTEM INCLUDING THE SAME

(71) Applicant: Samsung Display Co., LTD., Yongin-si (KR)

(72) Inventors: Jang Mi KANG, Yongin-si (KR); Min Kyu WOO, Yongin-si (KR); Byung Chang YU, Yongin-si (KR); Geun Ho LEE, Yongin-si (KR)

(21) Appl. No.: 19/081,632

(22) Filed: Mar. 17, 2025

(30) Foreign Application Priority Data
Jun. 18, 2024 (KR) 10-2024-0079020
Aug. 21, 2024 (KR) 10-2024-0112095

(51) Int. Cl. H10K 59/121; H10K 59/131

(52) U.S. Cl. CPC H10K 59/1213; H10K 59/131

(57) ABSTRACT

A display device includes: a pixel circuit layer including a plurality of sub-pixel circuits in a pixel circuit disposition area; and a display element layer including a plurality of light emitting elements connected to the plurality of sub-pixel circuits, the plurality of light emitting elements are in a display area overlapping the pixel circuit disposition area in a plan view, wherein, on the plan view, an area of the display area is less than an area of the pixel circuit disposition area.

### CROSS-REFERENCE TO RELATED APPLICATION

The present application claims priority to and the benefit of Korean Patent Application No. 10-2024-0079020, filed on Jun. 18, 2024, and Korean Patent Application No. 10-2024-0112095, filed on Aug. 21, 2024, in the Korean Intellectual Property Office, the entire disclosures of each of which are incorporated herein by reference.

### BACKGROUND

### 1. Field

Aspects of some embodiments of the present disclosure relate to a display device and a display system including the same.

### 2. Description of the Related Art

A display device is a device that displays images, and a display system may be various electronic devices including the display device. Recently, various studies for implementing a head mounted display device in which a distance between a user's eye and the display device is relatively small have been conducted.

The above information disclosed in this Background section is only for enhancement of understanding of the background and therefore the information discussed in this Background section does not necessarily constitute prior art.

### SUMMARY

When a distance between a user's eye and a display device is relatively small, such as in a head mounted display device, arranging light emitting elements included in the display device with very high resolution for relatively improved image quality may be desirable.

Aspects of some embodiments of the present disclosure include a display device and a display system including the same capable of implementing ultra-high resolution.

According to some embodiments of the present disclosure, a display device includes a pixel circuit layer including a plurality of sub-pixel circuits in a pixel circuit disposition area, and a display element layer including a plurality of light emitting elements connected to the plurality of sub-pixel circuits, the plurality of light emitting elements are in a display area overlapping the pixel circuit disposition area in a plan view, and in the plan view, an area of the display area is less than an area of the pixel circuit disposition area.

According to some embodiments, in a plan view, in the pixel circuit disposition area, the plurality of sub-pixel circuits may be arranged in a matrix form along a first direction and a second direction intersecting the first direction.

According to some embodiments, a width of the first direction of the display area may be less than a width of the first direction of the pixel circuit disposition area.

According to some embodiments, a width of the second direction of the display area may be less than a width of the second direction of the pixel circuit disposition area.

According to some embodiments, the plurality of sub-pixel circuits may correspond one-to-one with the plurality of light emitting elements.

According to some embodiments, each of the plurality of sub-pixel circuits may include at least one transistor, and the transistor may be a metal oxide semiconductor field effect transistor (MOSFET).

According to some embodiments, the display device may further include an extension line layer interposed between the pixel circuit layer and the display element layer.

According to some embodiments, the extension line layer may include a plurality of extension lines, one ends of the plurality of extension lines may be connected to the plurality of sub-pixel circuits, and other ends of the plurality of extension lines may be connected to the plurality of light emitting elements.

According to some embodiments, the plurality of extension lines may correspond one-to-one with the plurality of sub-pixel circuits and correspond one-to-one with the plurality of light emitting elements.

According to some embodiments, a display system includes a processor, a first display device connected to the processor, and a second display device connected to the processor. According to some embodiments, each of the first and second display devices includes a pixel circuit layer including a plurality of sub-pixel circuits in a pixel circuit disposition area, and a display element layer a plurality of light emitting elements connected to the plurality of sub-pixel circuits, the plurality of light emitting elements are in a display area overlapping the pixel circuit disposition area in a plan view, and an area of the display area in the plan view is less than an area of the pixel circuit disposition area.

According to some embodiments, the display system may be a head mounted display device.

According to some embodiments, in the plan view, in the pixel circuit disposition area, the plurality of sub-pixel circuits may be arranged in a matrix form along a first direction and a second direction intersecting the first direction.

According to some embodiments, a width of the first direction of the display area may be less than a width of the first direction of the pixel circuit disposition area.

According to some embodiments, a width of the second direction of the display area may be less than a width of the second direction of the pixel circuit disposition area.

According to some embodiments, the plurality of sub-pixel circuits may correspond one-to-one with the plurality of light emitting elements.

According to some embodiments, each of the plurality of sub-pixel circuits may include at least one transistor, and the transistor may be a metal oxide semiconductor field effect transistor (MOSFET).

According to some embodiments, each of the first and second display devices may include an extension line layer interposed between the pixel circuit layer and the display element layer.

According to some embodiments, the extension line layer may include a plurality of extension lines, one end of the plurality of extension lines may be connected to the plurality of sub-pixel circuits, and other ends of the plurality of extension lines may be connected to the plurality of light emitting elements.

According to some embodiments, the plurality of extension lines may correspond one-to-one with the plurality of sub-pixel circuits and correspond one-to-one with the plurality of light emitting elements.

According to some embodiments of the present disclosure, light emitting elements may be arranged with a high integration degree without needing to reduce a planar surface area of sub-pixel circuits having a limitation in high-resolution implementation.

### BRIEF DESCRIPTION OF THE DRAWINGS

The above and other features of embodiments according to the present disclosure will become more apparent by describing in further detail aspects of some embodiments thereof with reference to the accompanying drawings, in which:

FIG. 1 is a block diagram illustrating a display device according to some embodiments;

FIGS. 2 and 3 are drawings illustrating one of sub-pixels included in the display device of FIG. 1;

FIG. 4 is a drawing illustrating a display panel included in the display device of FIG. 1;

FIG. 5 is a cross-sectional view illustrating a stack structure of the display panel of FIG. 4;

FIG. 6 is a cross-sectional view illustrating a pixel circuit layer included in the display panel of FIG. 5;

FIG. 7 is a cross-sectional view illustrating an extension line layer included in the display panel of FIG. 5;

FIG. 8 is a cross-sectional view illustrating a display element layer included in the display panel of FIG. 5;

FIG. 9 is a drawing illustrating aspects of a light emitting structure included in the display element layer of FIG. 8;

FIG. 10 is a drawing illustrating further details of a light emitting structure included in the display element layer of FIG. 8;

FIG. 11 is a plan view illustrating components in a pixel circuit disposition area of the display panel of FIG. 5;

FIG. 12 is a plan view illustrating components in a display area of the display panel of FIG. 5;

FIG. 13 is a plan view illustrating components in a pixel circuit disposition area and a display area of the display panel of FIG. 5;

FIG. 14 is a block diagram illustrating further details of a display system;

FIG. 15 is a perspective view illustrating an application example of the display system of FIG. 14; and

FIG. 16 is a drawing illustrating a state in which a head mounted display device of FIG. 15 is worn by a user.

### DETAILED DESCRIPTION

Hereinafter, aspects of some embodiments according to the present disclosure are described in more detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiments described herein. However, the embodiments described herein are provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from an array configured of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in the disclosed embodiments, the term “under” may include both directions of on and under. In addition, the device may face in other directions (for example, rotated 90 degrees or in other directions) and thus the spatially relative terms used herein are interpreted according thereto.

Aspects of some embodiments are described in more detail with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

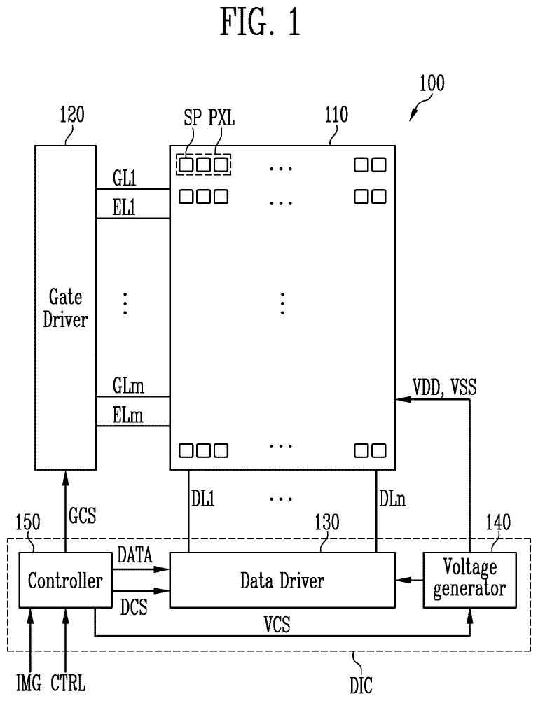

FIG. 1 is a block diagram illustrating a display device according to some embodiments.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among the sub-pixels SP may configure one pixel PXL. For example, as shown in FIG. 1, three sub-pixels may configure one pixel PXL.

The gate driver 120 may be connected to the sub-pixels SP arranged in a row direction through the first to m-th gate lines GL1 to GLm. The gate driver 120 may output scan signals to the first to m-th gate lines GL1 to GLm in response to a gate control signal GCS. According to some embodiments, the gate control signal GCS may include a start signal indicating a start of each frame, a horizontal synchronization signal for outputting the scan signals in synchronization with a timing at which data signals are applied, and the like.

According to some embodiments, first to m-th emission control lines EL1 to ELm connected to the sub-pixels SP of the row direction may be further provided. In this case, the gate driver 120 may include an emission driver configured to control the first to m-th emission control lines EL1 to ELm, and the emission driver may operate under control of the controller 150.

The gate driver 120 may be located on one side of the display panel 110. However, embodiments are not limited thereto. For example, the gate driver 120 may be divided into two or more physically and/or logically divided drivers, and such drivers may be located on one side of the display panel 110 and another side of the display panel 110 opposite the one side. As described above, the gate driver 120 may be arranged around the display panel 110 in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. According to some embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages received from the voltage generator 140. When the scan signal is applied to each of the first to m-th gate lines GL1 to GLm, the data signals corresponding to the image data DATA may be applied to the data lines DL1 to DLm. Accordingly, the corresponding sub-pixels SP may generate light corresponding to the data signals. Accordingly, an image may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. According to some embodiments, the first power voltage VDD or the second power voltage VSS may be provided from an output of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined reference voltage may be applied to the first to n-th data lines DL1 to DLn, and the voltage generator 140 may generate such a reference voltage.

The controller 150 may control overall operations of the display device 100. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. According to some embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. According to some embodiments, at least one of the data driver 130, the voltage generator 140, or the controller 150 may be provided as a component distinguished from the driver integrated circuit DIC.

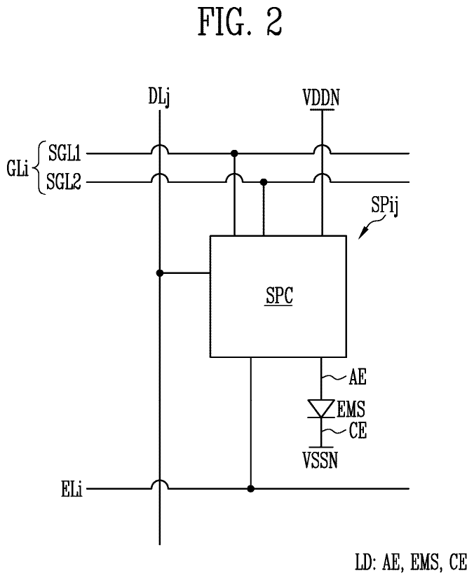

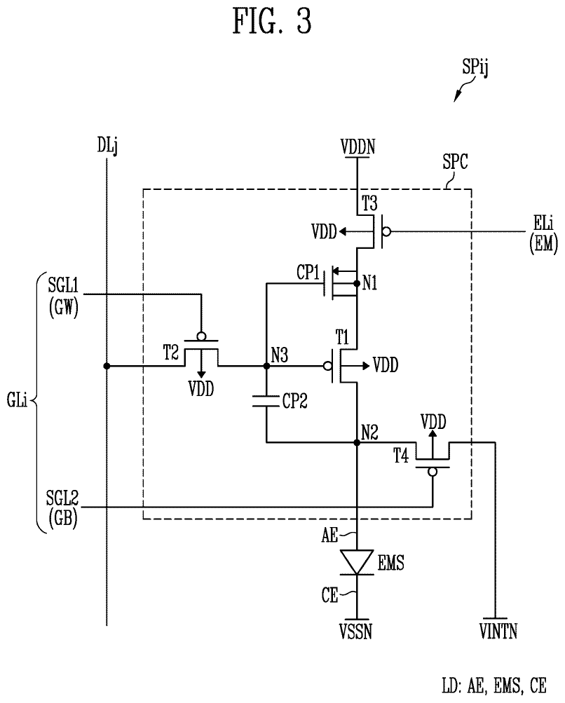

FIGS. 2 and 3 are drawings illustrating one of the sub-pixels included in the display device of FIG. 1. Although FIGS. 2 and 3 illustrate various components in a sub-pixel according to the present disclosure, embodiments according to the present disclosure are not limited thereto, and according to various embodiments, the sub-pixel may include additional components or fewer components without departing from the spirit and scope of embodiments according to the present disclosure.

In FIGS. 2 and 3, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may include an anode electrode AE, a cathode electrode CE, and a light emitting structure EMS connected between the anode electrode AE and the cathode electrode CE.

The anode electrode AE may be connected to a first power voltage node VDDN through the sub-pixel circuit SPC. For example, the anode electrode AE may be connected to the first power voltage node VDDN through one or more transistors included in the sub-pixel circuit SPC. Here, the first power voltage node VDDN may be a node that transmits the first power voltage VDD of FIG. 1.

The cathode electrode CE may be connected to a second power voltage node VSSN. Here, the second power voltage node VSSN may be a node that transmits the second power voltage VSS of FIG. 1.

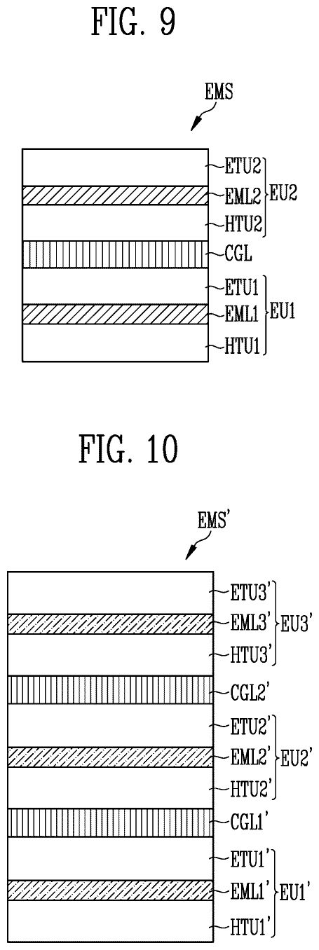

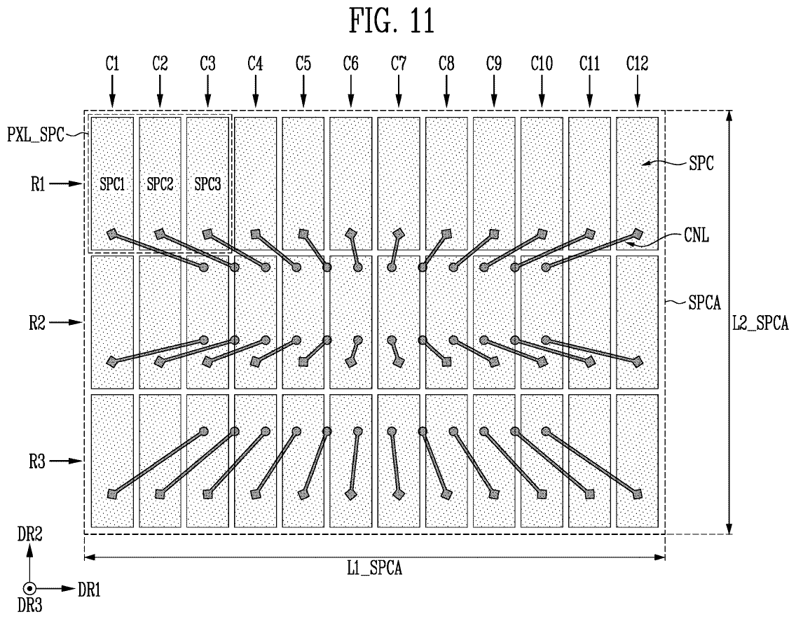

The light emitting structure EMS may generate light based on a difference between voltages provided from the anode electrode AE and the cathode electrode CE. According to some embodiments, the light emitting structure EMS may include an organic light emitting element. The light emitting structure EMS is described in detail with reference to FIGS. 9 and 10 described in more detail later. According to some embodiments, the light emitting structure EMS may include an inorganic light emitting element such as a micro LED or a quantum dot light emitting element.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may be configured to control the light emitting element LD according to signals received through such signal lines.

The sub-pixel circuit SPC may operate in response to a scan signal received through the i-th gate line GLi. The i-th gate line GLi may include one or more sub-gate lines. According to some embodiments, as shown in FIG. 2, the i-th gate line GLi may include first and second sub-gate lines SGL1 and SGL2. The sub-pixel circuit SPC may operate in response to scan signals received through the first and second sub-gate lines SGL1 and SGL2. As described above, when the i-th gate line GLi includes two or more sub-gate lines, the sub-pixel circuit SPC may operate in response to scan signals received through the corresponding sub-gate lines.

The sub-pixel circuit SPC may operate in response to an emission control signal received through the i-th emission control line ELi. According to some embodiments, the i-th emission control line ELi may include one or more sub-emission control lines. When the i-th emission control line ELi includes two or more sub- emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may generate a voltage corresponding to the data signals in response to at least one of the scan signals received through the first or second sub-gate lines SGL1 or SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

Referring to FIG. 3, according to some embodiments, the sub-pixel circuit SPC may include first to fourth transistors T1, T2, T3, and T4, a first capacitor CP1, and a second capacitor CP2.

The first to fourth transistors T1, T2, T3, and T4 may be metal oxide semiconductor field effect transistors (MOSFETs) including a body electrode. In this case, the first to fourth transistors T1, T2, T3, and T4 may be mounted in a narrow area, and thus the sub-pixel SPij may be applied to a high-resolution panel. According to some embodiments, the body electrode of the first to fourth transistors T1, T2, T3, and T4 may receive the first power voltage VDD.

The first to fourth transistors T1, T2, T3, and T4 may be formed as P-type transistors. However, this is exemplary, and at least one of the first to fourth transistors T1, T2, T3, or T4 may be replaced with an N-type transistor.

A first electrode of the first transistor T1 may be connected to a first node N1, and a second electrode may be connected to a second node N2. Here, being connected includes meaning of being electrically connected. A gate electrode of the first transistor T1 may be connected to a third node N3. The first node N1 may be a node to which a second electrode of the third transistor T3 is connected, and the second node N2 may be a node to which the anode electrode AE is connected. The first transistor T1 may control a current amount supplied from the first power voltage node VDDN to the second power voltage node VSSN via the light emitting element LD in response to a voltage of the third node N3.

The second transistor T2 may be connected between the data line DLj and the third node N3. A gate electrode of the second transistor T2 may be electrically connected to the first sub-gate line SGL1. The second transistor T2 may be turned on when a first scan signal GW is supplied to the first sub-gate line SGL1 to electrically connect the data line DLj and the third node N3.

A first electrode of the third transistor T3 may be electrically connected to the first power voltage node VDDN, and the second electrode may be connected to the first node N1. A gate electrode of the third transistor T3 may be electrically connected to the emission control line ELi. The third transistor T3 may be turned off when the emission control signal is supplied to the emission control line ELi (or when a disable emission control signal is supplied), and may be turned on when the emission control signal is not supplied (or when an enable emission control signal is supplied). When the third transistor T3 is turned off, the first power supply voltage node VDDN and the first node N1 may be electrically blocked.

A first electrode of the fourth transistor T4 may be connected to the second node N2, and a second electrode may be electrically connected to an initialization voltage node VINTN. The initialization voltage node VINTN may be configured to transmit the initialization voltage. The initialization voltage may be provided by the voltage generator 140 of FIG. 1. The initialization voltage may be set to a voltage at which the light emitting element LD is turned off when supplied to the anode electrode AE. The fourth transistor T4 may be turned on when a second scan signal GB is supplied to the second sub-gate line SGL2 to electrically connect the second node N2 and the initialization voltage node VINTN.

The first capacitor CP1 may be connected between the first node N1 and the third node N3. The first capacitor CP1 may be driven as a coupling capacitor and may transmit a voltage change amount of the first node N1 to the third node N3. In addition, the first capacitor CP1 may store the voltage of the third node N3. According to some embodiments, the first capacitor CP1 may be formed as a metal-oxide-semiconductor (MOS) capacitor. However, the first capacitor CP1 is not limited to the MOS capacitor. For example, the first capacitor CP1 may be formed as a metal-oxide-metal (MOM) capacitor, a metal-insulator-metal (MIM) capacitor, or a vertical native capacitor (VNCAP).

A first electrode of the second capacitor CP2 may be connected to the third node N3, and a second electrode may be connected to the second node N2. The second capacitor CP2 may be driven as a coupling capacitor and may transmit a voltage change amount of the second node N2 to the third node N3. According to some embodiments, the second capacitor CP2 may be formed as a capacitor of a type different from that of the first capacitor CP1. For example, the second capacitor CP2 may be formed as a MOM capacitor. However, the second capacitor CP2 is not limited to the MOM capacitor. For example, the second capacitor CP2 may be formed as a MOS capacitor, a MIM capacitor, or a VNCAP.

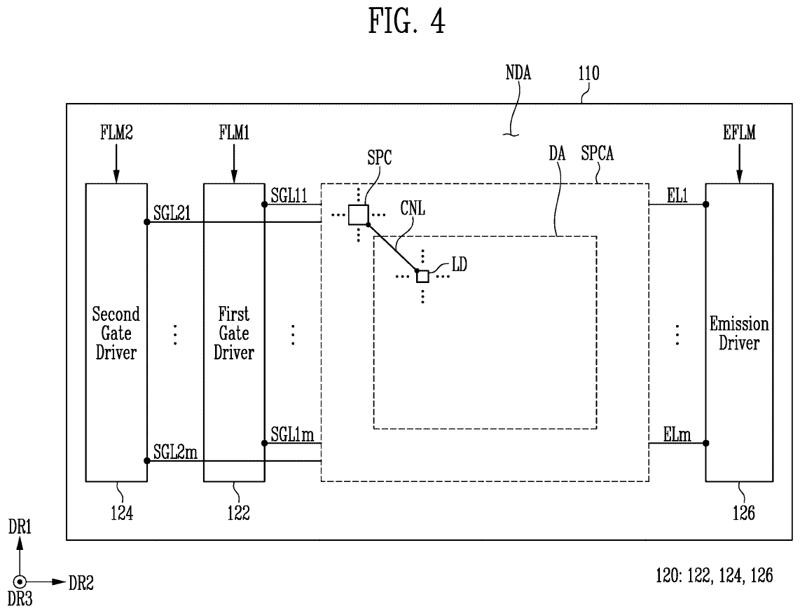

FIG. 4 is a drawing illustrating the display panel included in the display device of FIG. 1. The gate control signal GCS of FIG. 1 may include a first scan start signal FLM1, a second scan start signal FLM2, and an emission start signal EFLM. In addition, the gate control signal GCS of FIG. 1 may include clock signals.

Referring to FIG. 4, the display panel 110 may include a display area DA and a non-display area NDA. The display area DA may be an area where the light emitting elements LD are located, and may be an area where images are displayed. The non-display area NDA may be an area around (e.g., surrounding, in a periphery, or outside a footprint of) the display area DA, and may be an area where images are not displayed.

The display panel 110 may further include a pixel circuit disposition area SPCA. A portion of the pixel circuit disposition area SPCA may overlap the display area DA, and another portion may overlap the non-display area NDA adjacent to the display area DA. The pixel circuit disposition area SPCA may be an area where the sub-pixel circuits SPC are located.

The gate driver 120 may be located in the non-display area NDA that does not overlap the pixel circuit disposition area SPCA. The gate driver 120 may include a first gate driver 122, a second gate driver 124, and an emission driver 126.

The first gate driver 122 may receive the first scan start signal FLM1 and generate a first scan signal while shifting the first scan start signal FLM1 in response to the clock signal. The first gate driver 122 may sequentially supply the first scan signal to first sub-gate lines SGL11 to SGL1m. Here, the first sub-gate line SGL1 described with reference to FIG. 2 may be corresponding one of the first sub-gate lines SGL11 to SGL1m.

The second gate driver 124 may receive the second scan start signal FLM2 and generate a second scan signal while shifting the second scan start signal FLM2 in response to the clock signal. The second gate driver 124 may sequentially supply the second scan signal to second sub-gate lines SGL21 to SGL2m. Here, the second sub-gate line SGL2 described with reference to FIG. 2 may be corresponding one of the second sub-gate lines SGL21 to SGL2m.

The first scan signal and the second scan signal may be set to a gate on voltage so that a transistor included in the sub-pixel circuits SPC may be turned on.

For example, the first scan signal and the second scan signal of a logic low level may be supplied to a P-type transistor, and the first scan signal and the second scan signal of a logic high level may be supplied to an N-type transistor. A transistor receiving the first scan signal or the second scan signal may be turned on in response to the first scan signal or the second scan signal.

The emission driver 126 may generate the emission control signal while shifting the emission start signal EFLM in response to the clock signal. The emission driver 126 may sequentially supply the emission control signal to emission control lines EL1 to ELm. The emission control signal (or the disable emission control signal) may be set to a gate off voltage so that the transistor included in the sub-pixel circuits SPC may be turned off.

The sub-pixel circuits SPC may be located in the pixel circuit disposition area SPCA. The sub-pixel circuits SPC may be arranged entirely regularly in the pixel circuit disposition area SPCA. For example, the sub-pixel circuits SPC may be arranged in a matrix form along a first direction DR1 and a second direction DR2 intersecting the first direction DR1. In this case, as shown in FIG. 4, a portion of the sub-pixel circuits SPC may be arranged to overlap the display area DA, and another portion may be arranged to overlap the non-display area NDA adjacent to the display area DA.

The light emitting elements LD may be located in the display area DA. The light emitting elements LD may be arranged entirely regularly in the display area DA. For example, the light emitting elements LD may be arranged in a matrix form along the first direction DR1 and the second direction DR2 in the display area DA.

According to some embodiments, the light emitting elements LD may correspond one-to-one with the sub-pixel circuits SPC. In this case, extension lines CNL for connecting the light emitting elements LD and the sub-pixel circuits SPC may be provided. The extension lines CNL may correspond one-to-one with the light emitting elements LD and may correspond one-to-one with the sub-pixel circuits SPC. One ends of the extension lines CNL may be connected to the sub-pixel circuits SPC, and other ends may be connected to the light emitting elements LD.

As described above, in the disclosure, the display area DA where the light emitting elements LD are provided and the pixel circuit disposition area SPCA where the sub-pixel circuits SPC are provided may not coincide on a plane. Here, the plane may be defined as a plane parallel to a plane defined by the first direction DR1 and the second direction DR2, and perpendicular to a third direction DR3 perpendicular to the first and second directions DR1, DR2.

According to some embodiments, as shown in FIG. 4, the area of the display area DA may be less than the area of the pixel circuit disposition area SPCA. The planar area of each of the light emitting elements LD may be relatively less than that of each of the sub-pixel circuits SPC. In this case, arranging a relatively large number of sub-pixel circuits SPC in a limited area may be more difficult than arranging a relatively large number of light emitting elements LD in a limited area. According to some embodiments, as shown in FIG. 4, by setting the area of the display area DA to be less than the area of the pixel circuit disposition area SPCA, and connecting the light emitting elements LD located in the display area DA and the sub-pixel circuits SPC located in the pixel circuit disposition area SPCA, the light emitting elements LD may be arranged with high resolution regardless of an integration degree restriction of the sub-pixel circuit SPC.

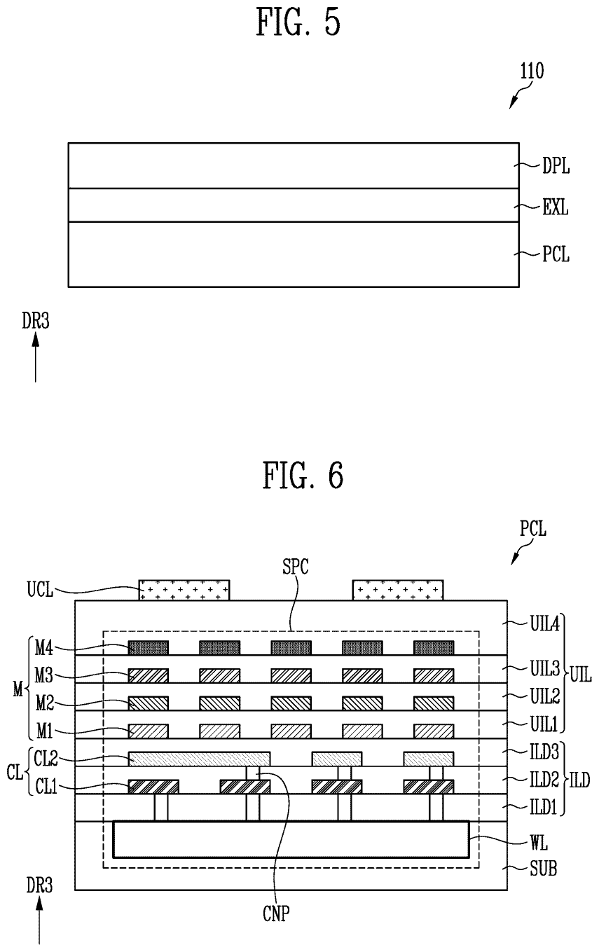

FIG. 5 is a cross-sectional view illustrating a stack structure of the display panel of FIG. 4.

Referring to FIG. 5, the display panel 110 may include a pixel circuit layer PCL, an extension line layer EXL, and a light emitting element layer DPL.

The pixel circuit layer PCL may include various types of circuit elements for implementing the sub-pixel circuits SPC. The extension line layer EXL may be located on the pixel circuit layer PCL. The extension line layer EXL may include extension lines CNL. The light emitting element layer DPL may be located on the extension line layer EXL. The light emitting element layer DPL may include the light emitting elements LD.

FIG. 6 is a cross-sectional view illustrating the pixel circuit layer included in the display panel of FIG. 5. With reference to FIG. 6, a cross-sectional structure of the pixel circuit layer PCL where circuit elements (for example, the first to fourth transistors T1, T2, T3, and T4, the first capacitor CP1, and the second capacitor CP2) configuring the sub-pixel circuit SPC and lines electrically connected to the sub-pixel circuit SPC according to embodiments may be formed is described.

Referring to FIGS. 5 and 6, the pixel circuit layer PCL may include a substrate SUB, conductive layers CL, conductive structure layers M, interlayer insulating layers ILD, upper insulating layers UIL, and an upper conductive layer UCL.

The substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like.

A well WL formed through an ion injection process may be located on the substrate SUB. A partial area of the well WL may form a first transistor electrode area of the transistors T1, T2, T3, and T4, another partial area of the well WL may form a second transistor electrode area of the transistors T1, T2, T3, and T4, and still another partial area of the well WL may form a channel area of the transistors T1, T2, T3, and T4.

According to some embodiments, the first transistor electrode area may be a source area and the second transistor electrode area may be a drain area. Alternatively, according to some embodiments, the first transistor electrode area may be a drain area and the second transistor electrode area may be a source area.

The conductive layers CL may form an electrode electrically connected to the first and second transistor electrode areas of the transistors T1, T2, T3, and T4 and may also form a gate electrode of the transistors T1, T2, T3, and T4. For example, at least a portion of the conductive layers CL may be electrically connected to the well WL through a contact member CNP. In addition, at least a portion of the conductive layers CL may form at least a portion of the first to third nodes N1, N2, and N3 described above with reference to FIG. 3. In addition, at least a portion of conductive structure layers M may form at least a portion of the first to third nodes N1, N2, and N3 described above with reference to FIG. 3. Accordingly, the substrate SUB and the conductive layers CL and the conductive structure layers M located on the substrate SUB may form the sub-pixel circuit SPC.

According to some embodiments, the conductive layers CL may form at least a portion of lines electrically connected to the sub-pixel circuit SPC. For example, the conductive layers CL may form at least a portion of the first and second sub-gate lines SGL1 and SGL2 and the emission control line.

According to some embodiments, portions of the well WL, the conductive layers CL, and the conductive structure layers M may be electrically connected to each other through a contact member CNP passing through at least one of the interlayer insulating layers ILD or the upper insulating layers UIL. According to some embodiments, the upper conductive layer UCL may be electrically connected to at least a portion of the conductive layers CL and the conductive structure layers M, and thus may electrically connect the sub-pixel circuit SPC and the extension lines CNL.

According to some embodiments, the conductive layers CL may include first and second conductive layers CL1 and CL2. According to some embodiments, the interlayer insulating layers ILD may include first to third interlayer insulating layers ILD1, ILD2, and ILD3. According to some embodiments, the conductive structure layers M may include first to fourth conductive structure layers M1, M2, M3, and M4. According to some embodiments, the upper insulating layers UIL may include first to fourth upper insulating layers UIL1, UIL2, UIL3, and UIL4. However, the disclosure is not limited thereto. The number of layers forming each of the conductive layers CL, the conductive structure layers M, the interlayer insulating layers ILD, and the upper insulating layers UIL may be appropriately changed.

According to some embodiments, the first to third interlayer insulating layers ILD1, ILD2, and ILD3 and the first to fourth upper insulating layers UIL1, UIL2, UIL3, and UIL4 may be located between the substrate SUB, the first and second conductive layers CL1 and CL2, the first to fourth conductive structure layers M1, M2, M3, and M4, and the upper conductive layer UCL.

According to some embodiments, the conductive layers CL and the conductive structure layers M may include various conductive materials. The interlayer insulating layers ILD and the upper insulating layers UIL may include an inorganic material. However, embodiments according to the present disclosure are not limited thereto.

According to some embodiments, the conductive structure layers M may be spaced further from the substrate SUB than the conductive layers CL. The conductive structure layers M may be spaced apart from the substrate SUB and secure an facing area between first and second electrodes forming the capacitors CP1 and CP2, and thus may allow a sufficient capacitance to be formed in the sub-pixel circuit SPC. The conductive structure layers M may be adjacent to the conductive layers CL adjacent to the substrate SUB in a thickness direction of the substrate SUB (for example, the third direction DR3) and may form a capacitance of the capacitors CP1 and CP2 at a height different from that of the conductive layers CL. Accordingly, a capacitance of the sub-pixel circuit SPC may be formed relatively greatly in a relatively narrow area.

According to some embodiments, at least a portion of the conductive structure layers M may form at least a portion of lines electrically connected to the sub-pixel circuit SPC. For example, at least one of the conductive structure layers M may form a data line.

That is, the conductive layers CL and the conductive structure layers M may form the sub-pixel circuit SPC and lines electrically connected to the sub-pixel circuit SPC. In order for the display device 100 (or the display panel 110) to have a high-resolution characteristic, the conductive layers CL and the conductive structure layers M may be required to be patterned in the relatively small area, but improving an integration degree of components configuring the sub-pixel circuit SPC may be limited.

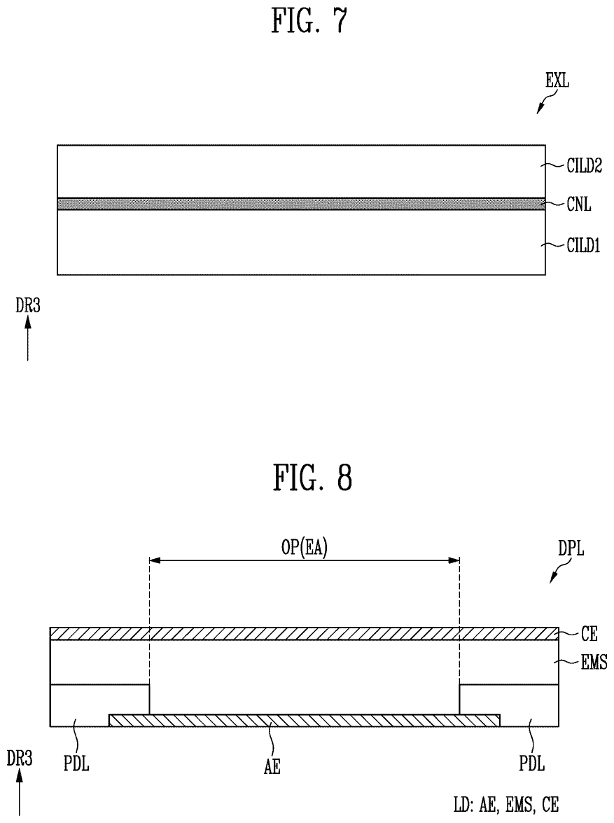

FIG. 7 is a cross-sectional view illustrating an extension line layer included in the display panel of FIG. 5.

Referring to FIG. 7, the extension line layer EXL may include a first insulating layer CILD1, a second insulating layer CILD2 located on the first insulating layer CILD1, and an extension line CNL interposed between the first and second insulating layers CILD1 and CILD2.

According to some embodiments, the extension line CNL may include various conductive materials. The first and second insulating layers CILD1 and CILD2 may include an inorganic material. However, embodiments according to the present disclosure are not limited thereto.

According to some embodiments, a portion of the extension line CNL may be connected to the upper conductive layer UCL through a through hole exposing the upper conductive layer UCL by passing through the first insulating layer CILD1. In addition, a portion of the extension line CNL may be exposed through a through hole passing through the second insulating layer CILD2, and the anode electrode AE located on the second insulating layer CILD2 may be connected to the extension line CNL through the through hole. Accordingly, the sub-pixel circuit SPC and the anode electrode AE may be electrically connected through the extension line CNL.

FIG. 8 is a cross-sectional view illustrating the display element layer included in the display panel of FIG. 5.

Referring to FIG. 8, the display element layer DPL may include the anode electrode AE, a pixel defining layer PDL, the light emitting structure EMS, and the cathode electrode CE. The anode electrode AE, the cathode electrode CE, and the light emitting structure EMS interposed therebetween may form the light emitting element LD.

The anode electrode AE may be located on the extension line layer EXL. The anode electrode AE may be connected to the sub-pixel circuit SPC through the extension line CNL, as described above. The anode electrode AE may include a conductive material suitable for reflecting light. However, a material of the anode electrode AE is not limited thereto.

The pixel defining layer PDL may be located on the anode electrode AE. The pixel defining layer PDL may include an opening OP exposing a portion of the anode electrode AE. An emission area EA of the light emitting element LD may be defined by the opening OP of the pixel defining layer PDL. The emission area EA may be an area where the light emitting element LD substantially generates (or emits) light.

According to embodiments, the pixel defining layer PDL may include a separator which causes a discontinuous portion (discontinuity) to be formed in the light emitting structure EMS, between the anode electrode AE and another anode electrode adjacent thereto.

According to embodiments, the pixel defining layer PDL may include an inorganic insulating material. In this case, the pixel defining layer PDL may include a plurality of stacked inorganic insulating layers. For example, the pixel defining layer PDL may include silicon oxide and silicon nitride sequentially stacked along the third direction DR3. According to some embodiments, the pixel defining layer PDL may include an organic insulating material. However, a material of the pixel defining layer PDL is not limited thereto.

The light emitting structure EMS may be located on the anode electrode AE exposed by the opening OP of the pixel defining layer PDL. The light emitting structure EMS may include a light emitting layer configured to generate light, an electron transport layer configured to transport an electron, a hole transport layer configured to transport a hole, and the like.

According to embodiments, the light emitting structure EMS may be entirely located on the pixel defining layer PDL while filling the opening OP of the pixel defining layer PDL. In this case, at least a portion of layers in the light emitting structure EMS may be disconnected or bent by the above-described separator or the like.

The cathode electrode CE may be located on the light emitting structure EMS. The cathode electrode CE may be entirely formed on the light emitting structure EMS. As described above, the cathode electrode CE may be provided as a common electrode.

The cathode electrode CE may be a thin metal layer having a thickness sufficient to transmit light emitted from the light emitting structure EMS. The cathode electrode CE may be formed of a metal material to have a relatively thin thickness, or may be formed of a transparent conductive material. For example, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the cathode electrode CE may include at least one of silver (Ag), magnesium (Mg), or a mixture thereof. However, a material of the cathode electrode CE is not limited thereto.

It may be understood that a portion of the anode electrode AE exposed by the opening OP, a portion of the light emitting structure EMS overlapping it, and a portion of the cathode electrode CE overlapping it configure one light emitting element LD. In this case, holes injected from the anode electrode AE and electrons injected from the cathode electrode CE may be transported into the light emitting layer of the light emitting structure EMS to form excitons, and light may be generated when the excitons transit from an excited state to a ground state. A luminance of the light may be determined according to a current amount flowing through the light emitting layer. A wavelength range of the generated light may be determined according to layers configuring the light emitting layer.

FIG. 9 is a drawing illustrating aspects of the light emitting structure included in the display element layer of FIG. 8.

Referring to FIG. 9, the light emitting structure EMS may have a tandem structure in which first and second light emitting units EU1 and EU2 are stacked.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be interposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be interposed between the second electron transport unit ETU2 and the second hole transport unit HTU2.

Each of the first and second hole transport units HTU1 and HTU2 may include at least one of a hole injection layer or a hole transport layer, and may further include a hole buffer layer, an electron blocking layer, and the like if necessary. The first and second hole transport units HTU1 and HTU2 may have configurations equal to each other or different from each other.

Each of the first and second electron transport units ETU1 or ETU2 may include at least one of an electron injection layer or an electron transport layer, and may further include an electron buffer layer, a hole blocking layer, and the like if necessary. The first and second electron transport units ETU1 and ETU2 may have configurations equal to each other or different from each other.

A charge generation layer CGL may be interposed between the first and second emitting units EU1 and EU2. The charge generation layer CGL may have a stack structure of, for example, a P-type dopant layer and an N-type dopant layer. For example, the P-type dopant layer may include a P-type dopant such as HAT-CN, TCNQ, and NDP-9, and the N-type dopant layer may include an alkali metal, an alkaline earth metal, a lanthanide metal, or a combination thereof. However, the disclosure is not limited thereto.

According to some embodiments, the first light emitting layer EML1 and the second light emitting layer EML2 may generate light of different colors. Light emitted from each of the first light emitting layer EML1 and the second light emitting layer EML2 may be mixed and viewed as white light. For example, the first light emitting layer EML1 may generate blue light, and the second light emitting layer EML2 may generate yellow light. According to some embodiments, the second light emitting layer EML2 may have a structure in which a first sub light emitting layer configured to generate red light and a second sub light emitting layer configured to generate green light are stacked. The red light and the green light may be mixed, and thus may be provided as the yellow light. In this case, an intermediate layer performing a function of transporting holes and/or blocking transportation of electrons may be further located between the first and second sub light emitting layers. According to some embodiments, the first light emitting layer EML1 and the second light emitting layer EML2 may generate light of the same color.

FIG. 10 is a drawing illustrating further details of the light emitting structure included in the display element layer of FIG. 8.

Referring to FIG. 10, the light emitting structure EMS′ may have a tandem structure in which first to third light emitting units EU1′, EU2′ and EU3′ are stacked.

Each of the first to third light emitting units EU1′, EU2′, and EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be interposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be located between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be located between the third electron transport unit ETU3′ and the third hole transport unit HTU3′.

Each of the first to third hole transport units HTU1′, HTU2, and HTU3′ may include at least one of a hole injection layer or a hole transport layer, and may further include a hole buffer layer, an electron blocking layer, and the like if necessary. The first to third hole transport units HTU1′, HTU2′, and HTU3′ may have configurations equal to each other or different from each other.

Each of the first to third electron transport units ETU1′, ETU2′ and ETU3′ may include at least one of an electron injection layer or an electron transport layer, and may further include an electron buffer layer, a hole blocking layer, and the like, if necessary. The first to third electron transport units ETU1′, ETU2′, and ETU3′ may have configurations equal to each other or different from each other.

A first charge generation layer CGL1′ may be interposed between the first light emitting unit EU1′ and the second light emitting unit EU2′. A second charge generation layer CGL2′ may be interposed between the second light emitting unit EU2′ and the third light emitting unit EU3′.

According to some embodiments, the first to third light emitting layers EML1′, EML2′, and EML3′ may generate light of different colors. Light emitted from each of the first to third light emitting layers EML1′, EML2′, and EML3′ may be mixed and may be viewed as white light. For example, the first emitting layer EML1′ may generate light of a blue color, the second emitting layer EML2′ may generate light of a green color, and the third emitting layer EML3′ may generate light of a red color. According to some embodiments, two or more of the first to third light emitting layers EML1′, EML2′, and EML3′ may also generate light of the same color.

FIG. 11 is a plan view illustrating components located in the pixel circuit disposition area of the display panel of FIG. 5.

Referring to FIG. 11, the sub-pixel circuits SPC may be located in the pixel circuit disposition area SPCA.

According to some embodiments, the sub-pixel circuits SPC may be arranged in a matrix form along the first and second directions DR1 and DR2. For example, the sub-pixel circuits SPC may be arranged in a 3*12 matrix form along first to third rows R1, R2, and R3 and first to twelfth columns C1, C2, C3, C4, C5, C6, C7, C8, C9, C10, C11, and C12. However, an arrangement of the sub-pixel circuits SPC is not limited thereto. For example, a greater number of sub-pixel circuits SPC may be arranged in the pixel circuit disposition area SPCA. As another example, the sub-pixel circuits SPC may be arranged in a zigzag form.

Among the sub-pixel circuits SPC, three sub-pixel circuits SPC1, SPC2, and SPC3 may form a pixel circuit unit PXL_SPC of one pixel PXL. In this case, it may be understood that pixel circuit units PXL_SPC arranged in a 3*4 matrix form in the pixel circuit disposition area SPCA are shown in FIG. 11.

The extension lines CNL may be located in the pixel circuit disposition area SPCA. The extension lines CNL may correspond one-to-one to the sub-pixel circuits SPC. One ends of the extension lines CNL may be connected to the sub-pixel circuits SPC. For example, one ends of the extension lines CNL shown as quadrangles in FIG. 11 may be connected to the sub-pixel circuits SPC overlapping therewith on a plane (or in a plan view).

The extension lines CNL may include first to third extension lines CNL1, CNL2, and CNL3 connected to the sub-pixel circuits SPC1, SPC2, and SPC3 configuring the pixel circuit unit PXL_SPC. One end of the first extension line CNL1 may be connected to the first sub-pixel circuit SPC1, one end of the second extension line CNL2 may be connected to the second sub-pixel circuit SPC2, and one end of the third extension line CNL3 may be connected to the third sub-pixel circuit SPC3.

Each of the extension lines CNL may extend in the first direction DR1, the second direction DR2, and/or directions intersecting the first and second directions DR1 and DR2.

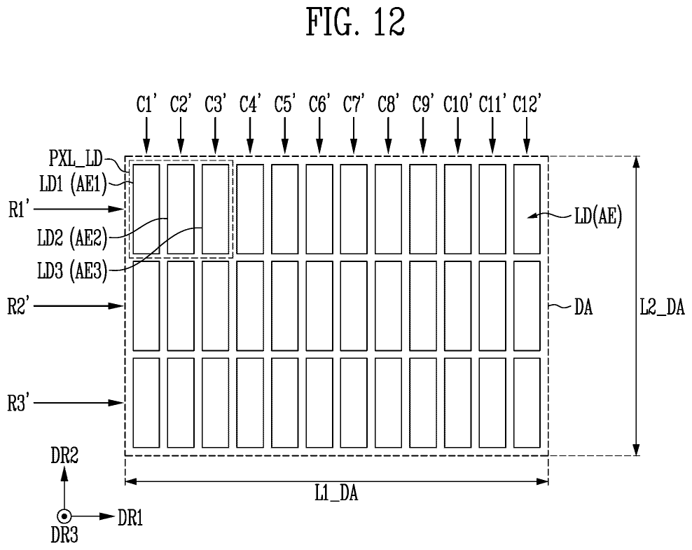

FIG. 12 is a plan view illustrating components located in the display area of the display panel of FIG. 5.

Referring to FIG. 12, the light emitting elements LD may be located in the display area DA. FIG. 12 may show the anode electrodes AE of the light emitting elements LD.

According to some embodiments, the light emitting elements LD may be arranged in a matrix form along the first and second directions DR1 and DR2. For example, the light emitting elements LD may be arranged in a 3*12 matrix form along first to third rows R1′, R2′, and R3′ and first to twelfth columns C1′, C2′, C3′, C4′, C5′, C6′, C7′, C8′, C9′, C10′, C11′, and C12′. However, an arrangement of the light emitting elements LD is not limited thereto. For example, a greater number of light emitting elements LD may be located in the display area DA. As another example, the light emitting elements LD may be arranged in a zigzag form.

Three light emitting elements LD1, LD2, and LD3 among the light emitting elements LD may configure a light emitting unit PXL_LD of one pixel PXL. In this case, it may be understood that the light emitting units PXL_LD arranged in a 3*4 matrix form in the display area DA are shown in FIG. 12.

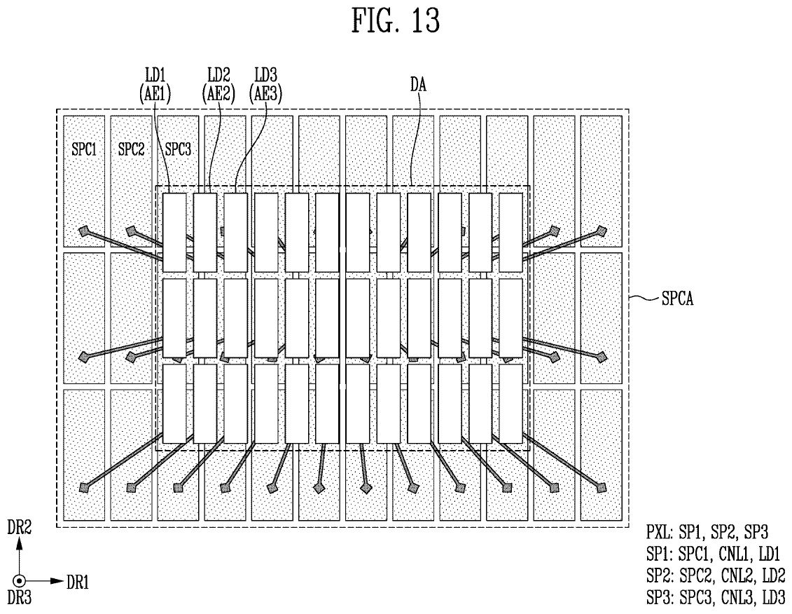

FIG. 13 is a plan view illustrating the pixel circuit disposition area of the display panel of FIG. 5 and components located in the display area.

Referring to FIGS. 11 to 13, the light emitting elements LD located in the display area DA and the sub-pixel circuits SPC located in the pixel circuit disposition area SPCA may be arranged to overlap each other on a plane (or in a plan view).

In this case, the light emitting elements LD having a relatively small planar surface area compared to that of each of the sub-pixel circuits SPC may be arranged with a high integration degree compared to the sub-pixel circuits SPC.

For example, a width L1_DA of the first direction DR1 of the display area DA may be less than a width L1_SPCA of the first direction DR1 of the pixel circuit disposition area SPCA. For example, the width L1_DA of the first direction DR1 of the display area DA may be about 95% or less, preferably, about 80% or less, of the width L1_SPCA of the first direction DR1 of the pixel circuit disposition area SPCA.

For example, a width L2_DA of the second direction DR2 of the display area DA may be less than a width L2_SPCA of the second direction DR2 of the pixel circuit disposition area SPCA. For example, the width L2_DA of the second direction DR2 of the display area DA may be about 95% or less, preferably, about 80% or less, of the width L2_SPCA of the second direction DR2 of the pixel circuit disposition area SPCA.

In this case, the light emitting elements LD may correspond one-to-one to the sub-pixels SPC, and the light emitting elements LD and the sub-pixel circuits SPC may be connected by the extension lines CNL. For example, other ends of the extension lines CNL shown as circles in FIG. 11 may be connected to the light emitting elements LD overlapping therewith on a plane (or in a plan view).

For example, the pixel PXL may include first to third sub-pixels SP1, SP2, and SP3. The first sub-pixel SP1 may include a first sub-pixel circuit SPC1, a first extension line CNL1, and a first light emitting element LD1. The second sub-pixel SP2 may include a second sub-pixel circuit SPC2, a second extension line CNL2, and a second light emitting element LD2. The third sub-pixel SP3 may include a third sub-pixel circuit SPC3, a third extension line CNL3, and a third light emitting element LD3.

One end of the first extension line CNL1 may be connected to the first sub-pixel circuit SPC1, and another end of the first extension line CNL1 may be connected to a first anode electrode AE1 of the first light emitting element LD1. One end of the second extension line CNL2 may be connected to the second sub-pixel circuit SPC2, and another end of the second extension line CNL2 may be connected to a second anode electrode AE2 of the second light emitting element LD2. One end of the third extension line CNL3 may be connected to the third sub-pixel circuit SPC3, and another end of the third extension line CNL3 may be connected to a third anode electrode AE3 of the third light emitting element LD3.

As described above, in the disclosure, the light emitting elements LD that are advantageous for high-resolution implementation as having a relatively small planar area may be arranged with a high integration degree without needing to reduce the planar area of sub-pixel circuits SPC having a limitation in high-resolution implementation.

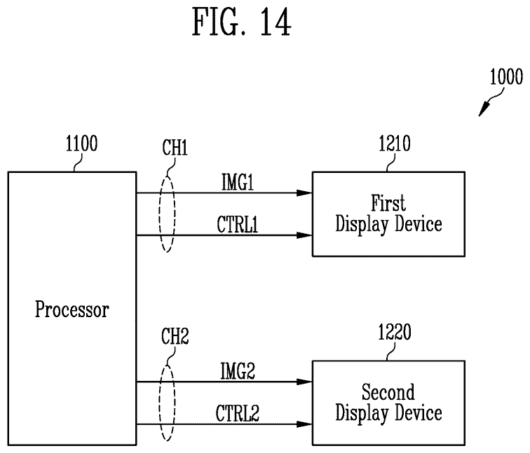

FIG. 14 is a block diagram illustrating further details of a display system according to some embodiments.

Referring to FIG. 14, the display system 1000 may include a processor 1100, a first display device 1210, and a second display device 1220.

The processor 1100 may perform various tasks and calculations. According to some embodiments, the processor 1100 may include an application processor, a graphic processor, a microprocessor, a central processing unit (CPU), and the like. The processor 1100 may be connected to other components of the display system 1000 through a bus system and may control the other components.

The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively. The first display device 1210 may be configured similarly to that described with reference to FIGS. 2 to 13.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively. The second display device 1220 may be configured similarly to that described with reference to FIGS. 2 to 13.

The display system 1000 may be implemented as at least one of a head mounted display (HMD) device, a virtual reality (VR) device, a mixed reality (MR) device, or an augmented reality (AR) device.

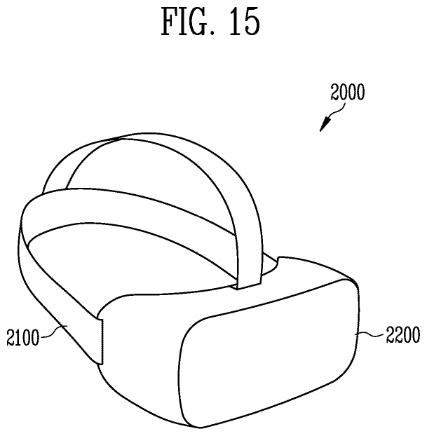

FIG. 15 is a perspective view illustrating an application example of the display system of FIG. 14.

Referring to FIG. 15, the display system 1000 of FIG. 14 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, embodiments are not limited thereto. For example, the head mount band 2100 may be implemented in a glasses frame form, a helmet form, or the like.

The display device receiving case 2200 may receive the first and second display devices 1210 and 1220 of FIG. 14. The display device receiving case 2200 may further receive the processor 1100 of FIG. 14.

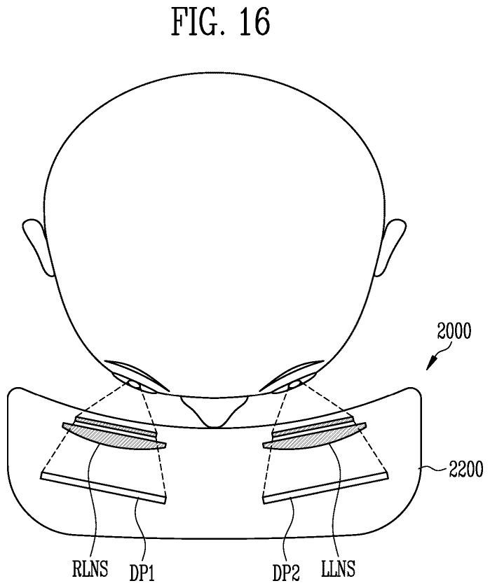

FIG. 16 is a drawing illustrating a state in which the head mounted display device of FIG. 15 is worn by a user.

Referring to FIG. 16, in the head mounted display device 2000, a first display panel DP1 of the first display device 1210 and a second display panel DP2 of the second display device 1220 may be arranged. The head mounted display device 2000 may further include one or more lenses LLNS and RLNS. Each of the first and second display panels DP1 and DP2 may be described similarly to that described with reference to FIGS. 4 to 13.

Within the display device receiving case 2200, the right eye lens RLNS may be arranged between the first display panel DP1 and a user's right eye. Within the display device receiving case 2200, the left eye lens LLNS may be arranged between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

According to some embodiments, each of the right eye lens RLNS and the left eye lens LLNS may include an optical lens having a pancake shape of cross-section. According to some embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

As shown in FIG. 16, a distance between the user's left eye and right eye and the first and second display panels DP1 and DP2 may be relatively close. In this case, in order to improve display quality of the image, the light emitting elements LD arranged in the display area DA may be required to be arranged with a very high integration degree.

Meanwhile, as described above with reference to FIGS. 11 to 13, in the disclosure, the light emitting elements LD that are advantageous for high-resolution implementation as having a relatively small planar area may be arranged with a high integration degree without needing to reduce the planar area of the sub-pixel circuits SPC having a limitation in high-resolution implementation. Accordingly, even though the distance between the user's left eye and right eye and the first and second display panels DP1 and DP2 is relatively close, an image of excellent quality may be provided.

Although the disclosure is described with reference to embodiments above, it will be understood that those skilled in the art may variously correct and change the disclosure without departing from the spirit and area of the disclosure described in the scope of the following patent claims.

What is claimed is:

1. A display device comprising:
a pixel circuit layer including a plurality of sub-pixel circuits in a pixel circuit disposition area; and
a display element layer including a plurality of light emitting elements connected to the plurality of sub-pixel circuits, the plurality of light emitting elements are in a display area overlapping the pixel circuit disposition area in a plan view,
wherein, on the plan view, an area of the display area is less than an area of the pixel circuit disposition area.

2. The display device according to claim 1, wherein, in the plan view, in the pixel circuit disposition area, the plurality of sub-pixel circuits are arranged in a matrix form along a first direction and a second direction intersecting the first direction.

3. The display device according to claim 2, wherein a width of the first direction of the display area is less than a width of the first direction of the pixel circuit disposition area.

4. The display device according to claim 2, wherein a width of the second direction of the display area is less than a width of the second direction of the pixel circuit disposition area.

5. The display device according to claim 1, wherein the plurality of sub-pixel circuits correspond one-to-one with the plurality of light emitting elements.

6. The display device according to claim 1, wherein each of the plurality of sub-pixel circuits includes at least one transistor, and
the transistor is a metal oxide semiconductor field effect transistor (MOSFET).

7. The display device according to claim 1, further comprising:
an extension line layer interposed between the pixel circuit layer and the display element layer.

8. The display device according to claim 7, wherein the extension line layer includes a plurality of extension lines,
one ends of the plurality of extension lines are connected to the plurality of sub- pixel circuits, and
other ends of the plurality of extension lines are connected to the plurality of light emitting elements.

9. The display device according to claim 8, wherein the plurality of extension lines correspond one-to-one with the plurality of sub-pixel circuits and correspond one-to-one with the plurality of light emitting elements.

10. A display system comprising:
a processor;
a first display device connected to the processor; and
a second display device connected to the processor,
wherein each of the first and second display devices comprises:
a pixel circuit layer including a plurality of sub-pixel circuits in a pixel circuit disposition area; and
a display element layer including a plurality of light emitting elements connected to the plurality of sub-pixel circuits, the plurality of light emitting elements are in a display area overlapping the pixel circuit disposition area in a plan view, and
an area of the display area in the plan view is less than an area of the pixel circuit disposition area.

11. The display system according to claim 10, wherein the display system is a head mounted display device.

12. The display system according to claim 10, wherein in the plan view, in the pixel circuit disposition area, the plurality of sub-pixel circuits are arranged in a matrix form along a first direction and a second direction intersecting the first direction.

13. The display system according to claim 12, wherein a width of the first direction of the display area is less than a width of the first direction of the pixel circuit disposition area.

14. The display system according to claim 12, wherein a width of the second direction of the display area is less than a width of the second direction of the pixel circuit disposition area.

15. The display system according to claim 10, wherein the plurality of sub-pixel circuits correspond one-to-one with the plurality of light emitting elements.

16. The display system according to claim 10, wherein each of the plurality of sub-pixel circuits includes at least one transistor, and
the transistor is a metal oxide semiconductor field effect transistor (MOSFET).

17. The display system according to claim 10, wherein each of the first and second display devices includes an extension line layer interposed between the pixel circuit layer and the display element layer.

18. The display system according to claim 17, wherein the extension line layer includes a plurality of extension lines,
one end of the plurality of extension lines is connected to the plurality of sub-pixel circuits, and
other ends of the plurality of extension lines are connected to the plurality of light emitting elements.

19. The display system according to claim 18, wherein the plurality of extension lines correspond one-to-one with the plurality of sub-pixel circuits and correspond one-to-one with the plurality of light emitting elements.
